(19) United States
(12) Patent Application Publication
(10) Pub. No.: US 2026/0247782 A1
(43) Pub. Date: Aug. 20, 2026

(54) SOLID FRISCH GRID DEVICE BASED ON PEROVSKITE MATERIAL AND PREPARATION METHOD THEREOF

(71) Applicant: SOOCHOW UNIVERSITY, Suzhou (CN)

(72) Inventors: Yihui HE, Suzhou (CN); Haoming QIN, Suzhou (CN); Bao XIAO, Suzhou (CN); Nannan SHEN, Suzhou (CN); Qihao SUN, Suzhou (CN)

(21) Appl. No.: 19/554,172

(22) Filed: Mar. 2, 2026

Related U.S. Application Data
(63) Continuation of application No. PCT/CN2024/140901, filed on Dec. 20, 2024.

(30) Foreign Application Priority Data
Oct. 11, 2024 (CN) 202411415000.8

(51) Int. Cl. H10K 30/40; G01T 1/185; G01T 1/24; H10K 30/89

(52) U.S. Cl. CPC H10K 30/40; G01T 1/185; G01T 1/24; H10K 30/89

(57) ABSTRACT

A solid Frisch grid device based on a perovskite material and a preparation method thereof are provided. The preparation method includes direct growth from a solution and mechanical processing, and others. The weighting potential distribution of the device is limited at the grid mesh, indicating that the grid electrode provides effective charge shielding. In addition, by comparing the weighting potential distributions at different grid meshes, it can be found that the solid Frisch grid structure used in the present invention can realize a more uniform and nearly ideal weighting potential distribution by adjusting the grid mesh parameters. Moreover, by further analyzing the signals from the anode, the cathode and the grid electrode as independent events, more accurate information such as pulse rise time and radiation interaction position can be obtained.

This application is a Continuation of PCT/CN2024/140901, filed on Dec. 20, 2024, which claims priority to Chinese Patent Application No. 202411415000.8, filed on Oct. 11, 2024, which is incorporated by reference for all purposes as if fully set forth herein.

### FIELD OF THE INVENTION

The present invention relates to the field of semiconductor detectors, and particularly to a solid Frisch grid device based on perovskite material and a preparation method thereof.

### DESCRIPTION OF THE RELATED ART

Gas ionization chamber is one of the first detectors used in nuclear science and application. The working principle is that under radiation conditions, gas molecules generate a large number of electron-ion pairs by ionization or excitation, and relevant radiation information is obtained by detecting the generated electrons and positive ions. It has the characteristics of simple structure and convenient production. In the gas ionization chamber, electrons possess a much smaller physical size and a longer mean free path compared to positive ions, making them the primary charge carriers collected in most configurations. However, electrons will collide in the process of movement and be captured to form negative ions, which leads to various charge effects such as diffusion, adsorption, recombination and drift in the gas ionization chamber, causing charge loss during the transport process of the carriers.

In the gas ionization chamber, the effective weight of electrons is small, and the drift speed is about 3 orders of magnitude higher than that of positive ions under the action of various charge effects. Therefore, when electrons drift to the anode, the positive ions will still induce a slow induced signal, which is not conducive to the rapid measurement of pulse signals, especially when detecting particles with directional ionization tract (FIGS. 1(a) and 1(b)). In view of the above problems, Frisch (Frisch O. British atomic energy report br-49[J]. Atomic Energy Research Establishment: Harwell, UK, 1944.) proposed a Frisch grid device structure (FIG. 1(c)). In the device, electrostatic shielding is established in a gas medium by a metal grid mesh, which can effectively shield the induced signal of positive ions in the drift process, thus realizing the signal collection from individual carriers (electrons). Experiments show that the device structure can accelerate the time response of the device by charge shielding of positive ions (FIG. 1(d)). Specifically, as shown in FIG. 1(b), the weighting potential in a planar device is linearly distributed, and the great difference in the mobility of two carriers will seriously affect the collection time of charges induced by radiation at different interaction positions, resulting in a sequential order of the induced charge termination nodes, thus affecting the final amplitude (FIG. 1(b)). In contrast, FIG. 1(c) shows the weighting potential distribution in a Frisch grid detector with an electrostatic shielding grid mesh, in which the grid electrode can effectively shield the induced charge of the slow carriers, so that the amplitude of the device depends only on the fast carriers. In this way, the rise time and amplitude of the carriers induced by radiation at different positions are basically the same (FIG. 1(d)), whereby the device can reflect the radiation energy more accurately.

Similar to the gas ionization chamber, a solid semiconductor material is used as a medium in a semiconductor detector (solid ionization chamber), and the electrostatic interaction between atoms of the material is inconsistent, leading to obvious difference in the transport of electrons and hole carriers. Due to the limitations in material synthesis and processing technology, it is impossible to build a shielding grid mesh in the semiconductor, so a solid Frisch grid detector similar to a gas ionization chamber detector cannot be attained so far. In 1998, McGregor (Mcgregor D, He Z, Seifert H, et al. CdZnTe semiconductor parallel strip Frisch grid radiation detectors [J]. IEEE Transactions on Nuclear Science, 1998, 45 (3): 443-449) obtained a virtual Frisch grid structure by using cadmium zinc telluride (CdZnTe) crystal based on the gas ionization chamber. As shown in FIG. 2(a), the virtual Frisch grid device adopts a planar structure composed of a cathode, a semiconductor material and an anode; then, an insulating layer is wrapped outside the crystal to shield the charge between a collecting electrode and a Frisch grid electrode; and finally, the Frisch grid electrode (metal electrode) is wrapped on the side close to the collecting electrode to obtain a charge shielding effect on the collector side. Further studies show that adding an insulating layer between the crystal and the grid electrode can effectively reduce the absorption of carriers by the grid electrode. The insulating layer has a small thickness, and is equivalent to a capacitor. The grid electrode can still induce signals during the drift process of the carriers (Montémont G, Argues M, Verger L, et al. A capacitive Frisch grid structure for CdZnTe detectors[C]. 2000 IEEE Nuclear Science Symposium. Conference Record (Cat. No. 00CH37149), 2000:4/9-412.). Since then, the virtual Frisch grid structure is also applied to TIBr (Hitomi K, Tada T, Onodera T, et al. TIBr capacitive Frisch grid detectors[J]. IEEE Transactions on Nuclear Science,2012, 60 (2): 1156-1161.), CdZnTeSe (Roy U N, Camarda G S, Cui Y, et al. Evaluation of CdZnTeSe as a high-quality gamma-ray spectroscopic material with better compositional homogeneity and reduced defects[J]. Scientific reports, 2019, 9 (1): 7303) and other semiconductor crystals to improve the energy spectral performance of the detector. However, the existing unipolar devices (hemispherical devices, and pixelated devices, etc.), including virtual Frisch grid, still have many problems, such as non-uniform weighting potential distribution and incomplete signal shielding, which disperse the distribution characteristics of the collected signals. Therefore, it is of great scientific significance and practical value to develop a device with optimized weighting potential distribution based on a semiconductor material for obtaining accurate energy spectrum information and reducing the signal rise time.

A new halide perovskite semiconductor, due to its excellent carrier transport performance and defect tolerance, is expected to become a new generation of room-temperature semiconductor materials for the detection of nuclear radiation. The unique advantages of halide perovskite are that it can be prepared by a low-temperature solution method, the device structure is more flexible, and the manufacturing cost of the device can be significantly reduced. Leveraging the compatibility of solution-based crystal growth, a conductive wire or grid electrode can be directly embedded during perovskite crystallization. This approach enables effective electrostatic shielding and optimization of the weighting potential, thereby facilitating the realization of a true solid-state Frisch grid device structure (FIGS. 3(a)-(h)). Up to now, the traditional room-temperature semiconductor detectors have utilized the virtual Frisch grid (VFG) structure to optimize the weighting potential distribution. A typical example of this architecture, based on cadmium zinc telluride (CZT), is schematically illustrated in FIG. 2(a). A cathode, cadmium zinc telluride and an anode are arranged into a simple planar (sandwich) device structure, and the anode serves as an electron collector. An insulating layer is conformally deposited around the crystal, and a metal grid electrode is patterned along the sidewall adjacent to the anode to provide electrostatic shielding.

In addition, for semiconductors, the researchers have also developed other unipolar detector devices, such as hemispherical, pixelated, coplanar grid detectors. The weighting potential distribution at the collecting electrode of these devices is similar to that of the virtual Frisch grid device.

Up to now, no real solid Frisch grid device is realized in traditional compound semiconductor detectors (such as CdTe and CdZnTe).

### SUMMARY OF THE INVENTION

The disadvantages of the prior art are as follows:
1. As shown in FIG. 2(a), the existing virtual Frisch grid device structure is mainly based on a planar device. With respect to the optimization of the weighting potential, the adjustable parameters are limited to the thickness and height of the insulating layer and the grid electrode height. Because the virtual Frisch grid only acts on an outer layer of the device, the adjustment of these parameters only has a limited effect on the optimization of the weighting potential. As shown in FIG. 2(b), the weighting potential of the virtual Frisch grid device is not uniform in the X and Y axial directions. That is, the weighting potential distribution at the center position tends to disperse towards the cathode, and the weighting potential distribution at the edge position tends to concentrate towards the anode. This non-uniformity of the weighting potential leads to inconsistent shielding effects at different positions, which leads to a complex pulse shape distribution and further limits the scope of application. In addition, the pulse waveform contains information such as the interaction depth and the drift time of carriers, and this non-uniform weighting potential will seriously weaken the temporal and spatial resolution of the device.
2. To ensure the shielding effect, the virtual Frisch grid device has relatively strict requirements on the crystal size and grid electrode height. In general, a virtual Frisch grid device requires a crystal with a square cross-section and an aspect ratio of 2:1 (height to width). To ensure an optimal shielding effect, the height of the grid electrode must be greater than or equal to the lateral dimensions of the crystal. Consequently, the virtual Frisch grid device is applicable to crystals in rectangular prism shape and the electrode direction is limited, so it is difficult to optimize the weighting potential by using large-area and low-height crystals.
3. In a hemispherical device, due to the non-uniform electric field distribution and the significant variation in pulse shape, it is impossible to further correct the signal electronically at present.
4. In a pixelated device, the device relies primarily on the small-pixel effect to achieve unipolar signals, and requires at least N² (N is the number of pixels) electronic readout channels, which greatly increases the design and readout complexity of the electronic system. Because of the expansion of the weighting potential, the induced charge regions between different pixels will overlap, causing charge sharing events and further increasing the difficulty of signal processing.

To solve the above technical problems, the present invention provides the following technical solutions.

The present invention provides a solid Frisch grid device based on a perovskite material, which includes a crystal and a grid mesh embedded in the crystal, where an anode and a cathode are respectively provided at two ends of the crystal, and the grid mesh, the anode and the cathode are arranged in parallel.

The grid mesh consists of several layers of grid electrode metal sheets and an insulating layer wrapping the metal sheets, where the grid electrode metal sheets are arranged between the cathode and the anode of the crystal. The crystal is selected from three-dimensional organic-inorganic hybrid perovskite, all-inorganic perovskite, two-dimensional perovskite, zero-dimensional perovskite or double perovskite.

Preferably, the three-dimensional organic-inorganic hybrid perovskite and all-inorganic perovskite have a chemical formula of APbX₃, where A is selected from, including, but not limited to, methylamine cation (MA⁺), formamidine cation (FA⁺) or Cs⁺, and X is selected from F⁻, Cl⁻, Br⁻ or I⁻. The two-dimensional perovskite has a chemical formula of A₃B₂X₉, where A is selected from, including, but not limited to, ammonium cation (NH₄⁺), methylamine cation (MA⁺), formamidine cation (FA⁺), Cs⁺ or Rb⁺, B is selected from Sb³⁺ or Bi³⁺, and X is selected from Br⁻ or I⁻. The zero-dimensional perovskite has a chemical formula of Cs₃Bi₂I₉, Cs₂TeI₆ or Cs₂TeBr₆. The double perovskite has a chemical formula of Cs₂AgBiBr₆.

Preferably, the material of the grid electrode metal sheet is selected from, including, but not limited to, gold, copper, tungsten or stainless steel.

Preferably, the shape of the grid mesh is selected from, including, but not limited to, a wire shape, a strip shape, a mesh shape, a hole shape and a honeycomb shape.

The grid electrode structure in the present invention includes, but is not limited to, various regular or irregular metal patterns such as wire shape, strip shape, mesh shape, hole shape, honeycomb shape, and combinations of the above various patterns (as shown in FIGS. 3(a)-3(d)).

Preferably, the grid mesh has a thickness of 1 nm-50 mm.

Preferably, the insulating layer has a thickness of 0 -500 um. There are cases where the insulating layer is not needed according to actual needs.

Preferably, the material of the insulating layer is selected from an inorganic insulating material or an organic insulating material. The inorganic insulating material is selected from, including, but not limited to, AlN, Al₂O₃ or SiO₂. The organic insulating material is selected from, including, but not limited to, perylene type C, perylene type N, polytetrafluoroethylene, paraffin or acrylic.

Preferably, the material of the anode and the cathode is selected from, including, but not limited to, platinum, gold, silver, gallium, indium, lead or bismuth.

The present invention also provides a method for preparing a solid Frisch grid device based on a perovskite material. The preparation method is selected from, including, but not limited to, one or more of direct crystal growth from a solution, mechanical processing and crystal bonding.

The method of direct crystal growth from a solution includes the following steps:
S11: placing a grid mesh on the top of a crystal, and growing the crystal in a precursor solution; and
S12: preparing an anode and a cathode respectively at the top and bottom of the crystal grown in Step S11, to obtain the solid Frisch grid device based on a perovskite material. The mechanical processing includes the following steps:
S21: cutting a crystal to form a cutting groove and embedding a grid mesh into the cutting groove;
S22: placing the crystal embedded with the grid mesh obtained in Step S21 in a precursor solution for growth; and
S23: preparing an anode and a cathode respectively at the top and bottom of the crystal grown in Step S22, to obtain the solid Frisch grid device based on a perovskite material. The crystal bonding includes the following steps:
S31: coating a precursor solution on the surface of a crystal A and covering with a grid mesh;

S32: covering the top of the crystal A covered with the grid mesh obtained in Step S31 with a crystal B;
S33: growing a crystal C in the gap between the crystal A and the crystal B obtained in Step S32 in the presence of the precursor solution, to obtain a crystal embedded with the grid mesh, where the composition of the crystal C and the crystal B is the same as that of the crystal A; and
S34: preparing an anode and a cathode respectively at the top and bottom of the crystal embedded with the grid mesh, to obtain the solid Frisch grid device based on a perovskite material.

Preferably, the precursor solution includes an organic solvent, and several metal salts as a solute, where the cations and anions in the metal salts are selected from chemical elements of the crystal.

Further, depending on different properties of perovskite crystals, the organic solvent is selected from solvents able to dissolve perovskite materials, including, but not limited to, one or more of dimethyl sulfoxide (DMSO), N,N-dimethylformamide (DMF) and y-butyrolactone (GBL).

Preferably, the organic solvent is dimethyl sulfoxide (DMSO).

Particularly, the Frisch grid device structure provided in the present invention can be prepared through various processes, including, but not limited to, the following three processes. Hereinafter, the description is made with cesium lead bromide (CsPbBr₃) perovskite crystal as an example.

Example 1 of a complete technical process of the present invention is shown in FIGS. 4(a)-4(f). The specific steps are as follows.
1. Seed crystal growth: As shown in FIG. 4(a), CsBr and PbBr₂ at a molar ratio of 1:2 dissolved in DMSO to form a precursor solution with a concentration of 0.9 mol/L to grow the seed crystal of CsPbBr₃. Suitable seed crystal is selected for subsequent crystal growth.
2. Crystal growth covering the grid mesh: As shown in FIG. 4(b), a grid mesh coated with an insulating layer is placed on a CsPbBr₃ seed crystal, which is then allowed to grow in the precursor solution until it fully covers the mesh and reaches the desired thickness (FIG. 4(c)).
3. Device preparation: The CsPbBr 3 crystal embedded with the grid mesh inside is taken out from the solution, and gold and gallium-indium alloy are respectively deposited on the top and the bottom surfaces of the crystal and used as the cathode and anode (FIGS. 4(d) and 4(e)), to obtain a solid Frisch grid detector based on the CsPbBr₃ crystal.
4. Device test: As shown in FIG. 4(f), a negative high voltage is applied to the cathode (gold electrode) of the solid Frisch grid detector, a positive high voltage is applied to the anode (gallium-indium alloy electrode), the grid electrode is either grounded or left floating, and the signal on the electrode is connected to a readout system, to obtain pulse waveform information or energy spectrum of the device.

Example 2 of a technical process for preparing a grid device of the present invention is shown in FIGS. 5(a)-5(d). The specific steps are as follows.
1. Crystal preparation: CsPbBr₃ single crystal with appropriate length, width and height dimensions is used for preparing a solid Frisch grid detector, as shown in FIG. 5(a).
2. Crystal processing: As shown in FIG. 5(b), one side of the CsPbBr₃ crystal is processed by a diamond wire cutting machine, laser cutting and other processing technologies to match with a grid mesh.
3. Embedding of grid mesh: The grid mesh with a certain size and shape is placed in the cutting groove and attached closely to the crystal, as shown in FIG. 5(c).
4. Crystal regrowth: The CsPbBr₃ crystal embedded with the grid mesh in a precursor solution in DMSO, and the CsPbBr₃ crystal is grown to fill the processed cutting groove, so that the grid mesh is embedded in the crystal, as shown in FIG. 5(d).
5. Refer to FIGS. 4(d)-4(f) for subsequent device preparation and test.

Example 3 of a technical process for preparing a grid device of the present invention is shown in FIGS. 6(a)-6(d). The specific steps are as follows.
1. Crystal preparation: As shown in FIG. 6(a), CsPbBr₃ crystal A and B with appropriate shape and dimensions are used for preparing a solid Frisch grid detector.
2. Dripping of the solution: As shown in FIG. 6(b), a precursor solution in DMSO is dripped on the top surface of CsPbBr₃ crystal A for subsequent growth.
3. Covering grid mesh and crystal: As shown in FIG. 6(c), a grid mesh with a certain size and shape and CsPbBr₃ crystal B are sequentially covered on CsPbBr₃ crystal A and the precursor solution.
4. Growth in crystal gap: As shown in FIG. 6(d), in the presence of the precursor solution, CsPbBr₃ is grown in the gap between crystals A and B, to adjoin two crystals A and B, and finally obtain CsPbBr₃ crystal embedded with the grid mesh.
5. Refer to FIGS. 4(d)-4(f) for subsequent device preparation and test.

In view of the inherent defects of the existing virtual Frisch grid structure, the present invention provides a solid Frisch grid device based on a perovskite semiconductor material. The specific preparation methods include direct growth from a solution and mechanical processing, and others. FIGS. 3(a)-3(d) show four different types of grids mesh designed (note: the present invention is not limited to the four types of grids mesh, and honeycomb, irregular polygon and other shapes may be included), and the distribution diagrams of the corresponding weighting potential in the Y and Z directions at X=1.5 mm are shown in FIGS. 3(e)-3(h). As can be obviously seen from these figures, the weighting potential distribution of the device is sharply confined at the grid mesh, indicating that the grid electrode can have a good charge shielding effect. In addition, by comparing the weighting potential distributions at different grid meshes, it can be found that the solid Frisch grid structure used in the present invention can realize a more uniform and nearly ideal weighting potential distribution by adjusting the grid mesh parameters. In addition, by further analyzing the signals from the anode, the cathode and the grid electrode as independent events, more accurate information such as pulse rise time and radiation interaction position can be obtained. The solid Frisch grid structure of the present invention is applicable to perovskite crystals of all sizes and can be used as an effective approach for optimizing the weighting potential of the semiconductor detector. Moreover, compared with a pixelated device, the readout system of the solid Frisch grid device requires only a single-channel readout without complex pulse-shape correction.

Compared with the prior art, the technical solution of the present invention has the following advantages.

According to the present invention, by taking the advantages of the halide perovskite that it can be prepared by a low-temperature solution method and has high defect tolerance, a crystal with a Frisch grid structure is obtained by direct growth, to realize a real solid Frisch grid device structure. The following problems are solved in the present invention:
1. Compared with the existing unipolar devices, the present invention embeds a conductive grid electrode directly within the crystal bulk. As shown in FIGS. 3(a)-(h), this physical grid effectively confines the weighting potential to the region between the cathode and the grid. As a result, the charge collection signal exhibits reduced rise-time variation and improved timing resolution.
2. In the present invention, by adjusting the grid mesh parameters, such as the height of the grid electrode (distance between the grid electrode and the collecting electrode), the thickness of the grid electrode, the aperture size of the grid mesh, and the thickness of the insulating layer, different weighting potential distributions can be obtained, and the distribution is more uniform and controllable. As the thickness of the grid decreases, its influence on the crystal growth becomes smaller, which is beneficial to obtaining a large-size crystal and increasing the detection volume. However, the shielding effect increases with the increase of the thickness of the grid electrode. As the distance between the grid electrode and the collector decreases, the weighting potential will be more concentrated toward the collector. The denser the grid mesh (the smaller the aperture) is, the more uniform the weighting potential distribution in the horizontal plane will be. Compared with the virtual Frisch grid device, the applicable crystal size is wider.
3. The grid mesh structure embedded in the crystal improves the uniformity of the weighting potential distribution, and makes the signal inflection point at the grid electrode clear. According to the drift time, the interaction position of the radiation between the grid electrode and the non-collecting electrode can be determined, so the present invention has a higher spatial resolution compared with the virtual Frisch grid.
4. Compared with the pixelated device, the structure of the present invention is improved on the basis of the planar device, and the readout electrodes only include a cathode, an anode and a grid electrode, which greatly simplifies the readout difficulty in front-end electronics.

### BRIEF DESCRIPTION OF THE DRAWINGS

FIG. 1(a) is a schematic diagram showing a planar device and a weighting potential distribution; FIG. 1(b) is a schematic diagram showing the rise time and amplitude at different radiation interaction positions in the planar device; FIG. 1(c) is a schematic diagram showing a Frisch grid device and a weighting potential distribution; and FIG. 1(d) is a schematic diagram showing the rise time and amplitude at different radiation interaction positions in the Frisch grid device.

FIG. 2(a) is a schematic diagram showing a virtual Frisch grid device structure of cadmium zinc telluride crystal; and FIG. 2(b) shows the weighting potential distribution of a cadmium zinc telluride-based virtual Frisch grid detector with a crystal size of 3.1×3.1×4.0 mm³ and a grid electrode height of 1 mm at a cross section where X=1.5 mm.

FIGS. 3(a)-3(h) show a schematic diagram showing Frisch grid mesh structure of (a) a mesh shape, (b) a hole shape, (c) an elongated hole shape, and (d) a wire shape, and (e-h) show the weighting potential distribution of the corresponding solid Frisch grid detectors at a cross section where X =1.5 mm.

FIGS. 4(a)-4(f) show a schematic diagram showing the preparation of a solid Frisch grid device based on CsPbBr₃ crystal: (a) seed crystal growth; (b) addition of grid mesh; (c) crystal growth covering the grid mesh; (d) cathode preparation; (e) anode preparation; and (f) signal collection.

FIGS. 5(a)-5(d) show a second schematic diagram showing the preparation of a solid Frisch grid device based on CsPbBr₃ crystal: (a) crystal preparation; (b) crystal processing; (c) embedding of grid mesh; and (d) crystal growth.

FIGS. 6(a)-6(d) show a third schematic diagram showing the preparation of a solid Frisch grid device based on CsPbBr₃ crystal: (a) crystal preparation; (b) dripping of precursor solution for CsPbBr₃ growth; (c) covering grid mesh and crystal; and (d) crystal growth.

FIG. 7(a) shows the weighting potential distributions of a grid mesh-type solid Frisch grid device at various grid electrode heights, where the weighting potential increases sharply near the grid electrode; FIG. 7(b) compares the pulse waveforms of a cathode, a anode and a grid electrode of a solid Frisch grid device, where the illustration shows CsPbBr₃ solid Frisch grid crystal grown in Example 1; FIG. 7(c) is a scatter diagram showing the 137Cs pulse height and drift time distribution of a CsPbBr₃-based solid Frisch grid detector; and FIG. 7(d) shows a 137Cs spectrum after height correction.

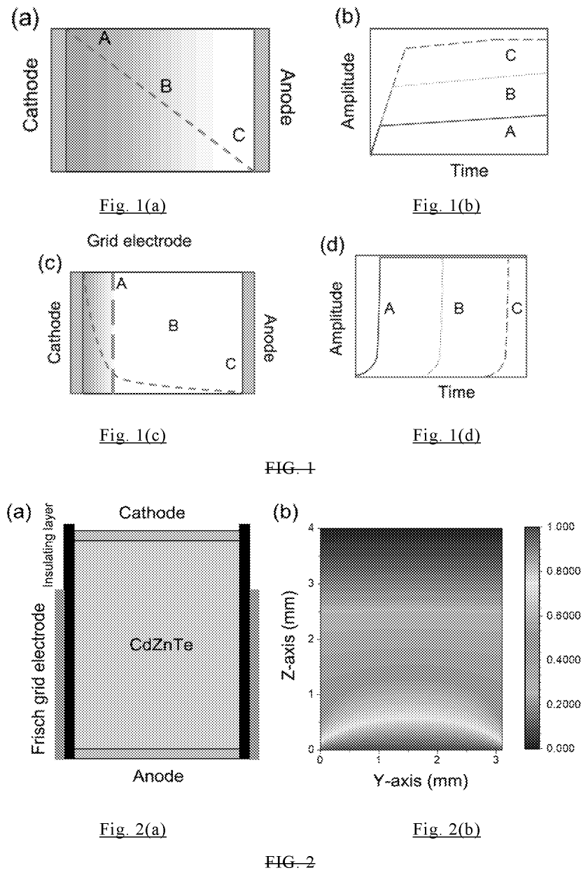

### DETAILED DESCRIPTION OF THE PREFERRED EMBODIMENTS

The present invention will be further described below with reference to the accompanying drawings and specific examples, so that those skilled in the art can better understand and implement the present invention; however, the present invention is not limited.

### Example 1

CsBr and PbBr₂ were dissolved in DMSO at a molar ratio of 1:2 with a concentration of about 0.9 mol/L, heated to 60° C. with stirring to dissolve them completely. The solution was filtered through 0.22 μm PTFE to obtain a clear saturated precursor solution. Subsequently, CsPbBr₃ crystal was grown by inverse temperature crystallization. When the crystal grew to about 1 mm, a copper mesh-type grid (with a grid thickness of 0.05 mm) coated with a 10 μm-thick Al₂O₃ insulating layer was placed on the crystal. The crystal was allowed to further grow in the precursor solution to pass through the grid mesh. When the grid was perfectly embedded in the crystal and the crystal grew to a certain size, the product was taken out. A cathode was prepared with a gold paste on the bottom surface of the crystal, and an anode was prepared with a gallium-indium alloy on the top surface, to obtain a mesh-type solid Frisch grid device based on the CsPbBr₃ crystal. The signals of the cathode, the anode and the grid electrodes were electrically connected via conductive leads, a negative high voltage was applied to the cathode, a positive high voltage was applied to the anode, and no voltage was applied to the grid electrode. The signal response and energy spectrum of the device were obtained using a standard radiation detection setup.

### Example 2

CsBr and PbBr₂ were dissolved in DMSO at a molar ratio of 1:2 and a concentration of about 0.9 mol/L, and heated to 60° C. with stirring to dissolve them completely. The solution was filtered through 0.22 um PTFE to obtain a clear saturated precursor solution. Subsequently, CsPbBr₃ crystal was grown by inverse temperature crystallization. When the crystal grew to about 1 mm, a stainless-steel wire-type grid (with a grid diameter of 0.01 mm) coated with a 50 μm-thick SiO₂ insulating layer was placed on the crystal. The crystal was allowed to further grow in the precursor solution to pass through the grid mesh. When the grid was perfectly embedded in the crystal and the crystal grew to a certain size, the product was taken out. A cathode was prepared with a gold paste on the bottom surface of the crystal, and an anode was prepared by vapor deposition of bismuth on the top surface, to obtain a wire-shaped solid Frisch grid device based on the CsPbBr₃ crystal. The signals of the cathode, the anode and the grid electrodes were electrically connected via conductive leads, a negative high voltage was applied to the cathode, a positive high voltage was applied to the anode, and no voltage was applied to the grid electrode. The signal response and energy spectrum of the device were obtained using a standard radiation detection setup.

### Example 3

A γ-butyrolactone solution having a concentration of 1.5 mol/L containing MAI and PbI₂ at a molar ratio of 1:1 was used as a precursor solution, and MAPbI₃ crystal was grown by inverse temperature crystallization. The crystal was used as seed crystal when it was grown to about 1 mm. A gold grid with perylene type C as an insulating layer (thickness 500 μm) was placed on the seed crystal. The crystal was allowed to further grow in the precursor solution to pass through the grid mesh. When the grid mesh was embedded in the crystal and the crystal grew to a certain size, the product was taken out. A cathode was prepared by sputtering platinum on the bottom surface of the crystal, and an anode was prepared by vapor deposition of metal indium on the top surface, to obtain a hole-type solid Frisch grid device based on the MAPbI₃ crystal. The signals of the cathode, the anode and the grid electrodes were electrically connected via conductive leads, a negative high voltage was applied to the cathode, a positive high voltage was applied to the anode, and no voltage was applied to the grid electrode. The signal response and energy spectrum of the device were obtained using a standard radiation detection setup.

### Example 4

CsPbBr₃ crystal was grown by Bridgeman method with CsBr and PbBr₂ at a molar ratio of 1:1. A crystal of 2×2×4 mm³ was obtained by grinding and polishing. One side of the crystal was processed by a wire cutting machine, to match the cutting groove with the grid mesh. A grid mesh with a thickness of 0.1 mm, a wire diameter of 0.01 mm and a wire spacing of 1 mm was embedded in the cutting groove. The crystal and the grid mesh were placed in a CsPbBr₃ solution for crystal regrowth, and the voids between the grid wires were filled via secondary crystal growth. CsPbBr₃ crystal with a grid mesh was obtained. A cathode was prepared with a gold paste on the bottom surface of the crystal, and an anode was prepared with a gallium-indium alloy on the top surface, to obtain a mesh-type solid Frisch grid device based on the CsPbBr₃ crystal. The signals of the cathode, the anode and the grid electrodes were electrically connected via conductive leads, a negative high voltage was applied to the cathode, a positive high voltage was applied to the anode, and no voltage was applied to the grid electrode. The signal response and energy spectrum of the device were obtained using a standard radiation detection setup.

### Example 5

CsPbBr₃ crystal was grown by Bridgeman method with CsBr and PbBr₂ at a molar ratio of 1:1. Crystal A and crystal B in the dimension of 2×2×2 mm³ were obtained by grinding and polishing. A saturated CsPbBr₃ solution was dripped on crystal A, and then covered the grid mesh and crystal B. The solvent was allowed to evaporate slowly under controlled conditions, resulting in the deposition of CsPbBrs material within the interstitial gap, which bonded crystal A, the grid mesh, and crystal B into an integrated structure. CsPbBr₃ crystal with a grid mesh was obtained. A cathode was prepared with a gold paste on the bottom surface of the crystal, and an anode was prepared with a gallium-indium alloy on the top surface, to obtain a mesh-type solid Frisch grid device based on the CsPbBr₃ crystal. The signals of the cathode, the anode and the grid electrodes were electrically connected via conductive leads, a negative high voltage was applied to the cathode, a positive high voltage was applied to the anode, and no voltage was applied to the grid electrode. The signal response and energy spectrum of the device were obtained using a standard radiation detection setup.

### Performance Evaluation 1

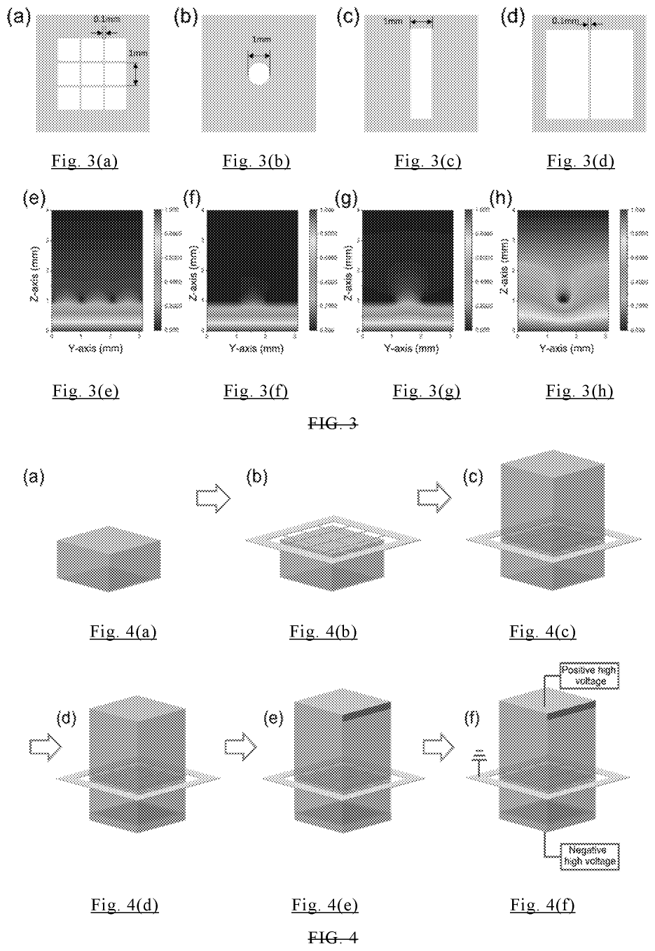

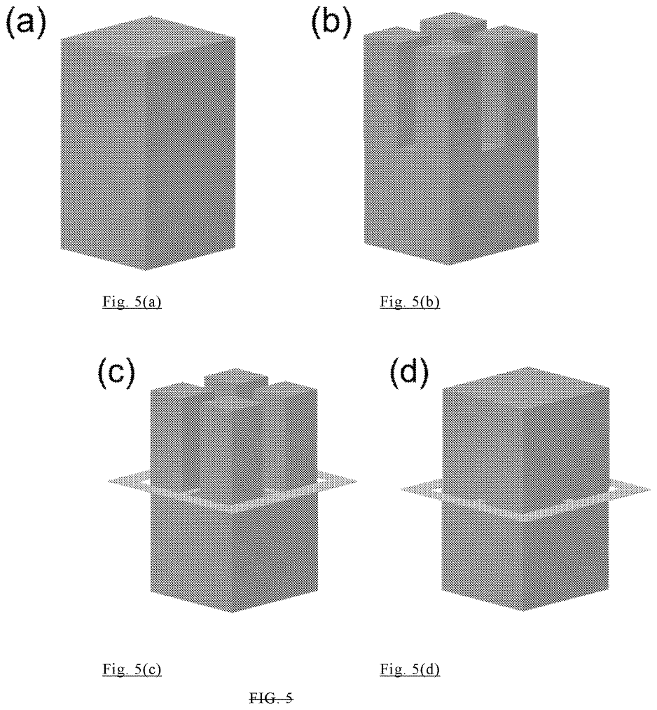

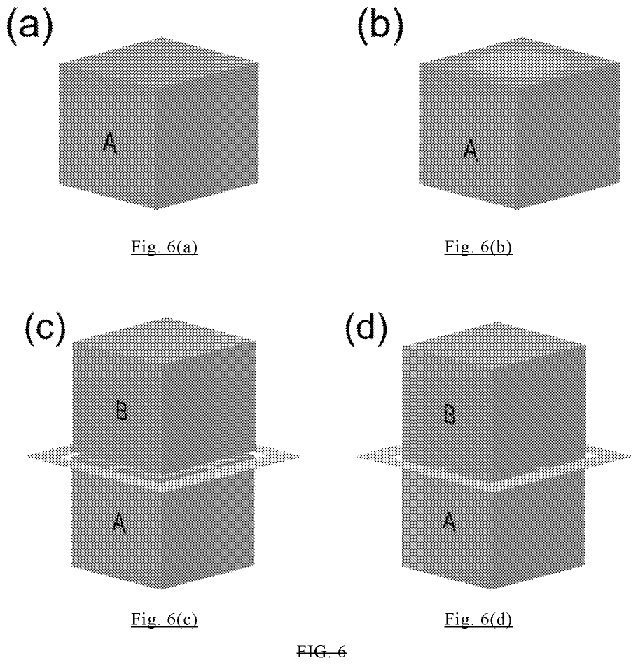

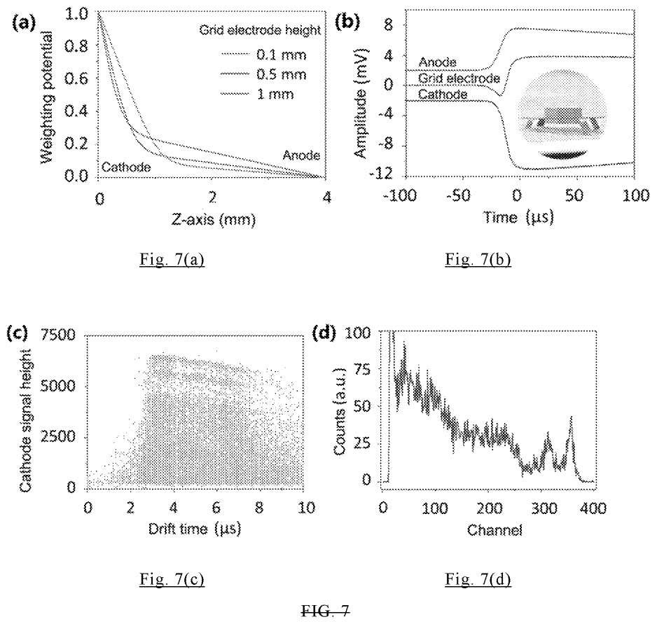

Based on the weighting potential distribution of the solid Frisch grid device in FIG. 3(e), the weighting potential distributions along the Z axial direction at X=1.5 mm and Y=1.5 mm can be obtained by adjusting the grid electrode height, as shown in FIG. 7(a). As can be seen, the grid electrode height significantly affects the weighting potential distribution of the device, with the shielding effect decreasing with the decrease of the grid electrode height. Only when the grid electrode height of the device is 1 mm, the weighting potential distribution on the anode side can be confined to a low level, and the induced charges generated by the motion of charge carriers in this region are low. FIG. 7(b) shows the pulse waveforms of the anode, the grid electrode and the cathode of the solid Frisch grid detector based on CsPbBr₃ crystal, where the illustration shows CsPbBr₃ solid Frisch grid grown in Example 1. As can be seen, in the initial stage, the anode responds earlier than the cathode, indicating that the radiation acts on the area between the anode and the grid electrode at this time. When the generated carriers begin to drift under the electric field, the anode and the grid electrode respectively generate an induced signal with an opposite direction (i.e., the anode signal is positive and the grid electrode signal is negative). When the carriers pass through the grid electrode and move away from the grid electrode, the anode signal is shielded by the grid electrode, the induced signal decreases, and the anode signal height reaches the maximum and begins to decline before the cathode and the grid electrode; the cathode signal starts to increase rapidly due to the hole carriers induced by the cathode passing through a large weighting potential difference, and the signal direction is negative; and the grid electrode begins to generate a positive signal, thus showing a bipolar signal. According to the prepared solid Frisch grid device, a scatter plots of the distribution of cathode signal height and the drift time in response to 662 keV ¹³⁷Cs γ radiation as shown in FIG. 7(c) is obtained. Two scatter distributions with the same slope are shown at the top of the diagram, which correspond to the 662 keV full-energy peak of ¹³⁷Cs and the escape peak of Pb respectively. In addition, the cathode signal height declines by up to about 10% with the extension of the drift time, which shows that the carrier ut product of CsPbBr₃ crystal grown by the solution method is low, causing decline in the drift process. As the distance from the grid electrode increases, the decline becomes more serious. It is also verified that the radiation energy and position information in the whole deposition range can be obtained by the prepared solid Frisch grid device. Then, the pulse heights at various drift times are subjected to energy correction, as shown in FIG. 7(d).

Apparently, the above-described embodiments are merely examples provided for clarity of description, and are not intended to limit the implementations of the present invention. Other variations or changes can be made by those skilled in the art based on the above description. The embodiments are not exhaustive herein. Obvious variations or changes derived therefrom also fall within the protection scope of the present invention.

1. A solid Frisch grid device based on a perovskite material, comprising a crystal and a grid mesh embedded in the crystal, wherein an anode and a cathode are respectively provided at two ends of the crystal, and the grid mesh, the anode and the cathode are arranged in parallel; and
the grid mesh comprises several layers of grid electrode metal sheets and an insulating layer wrapping the grid electrode metal sheets, wherein the grid electrode metal sheets are arranged between the cathode and the anode of the crystal; and the crystal is selected from three-dimensional organic-inorganic hybrid perovskite, all-inorganic perovskite, two-dimensional perovskite, zero-dimensional perovskite or double perovskite.

2. The solid Frisch grid device based on a perovskite material according to claim 1, wherein the three-dimensional organic-inorganic hybrid perovskite or all-inorganic perovskite has a chemical formula of APbX₃, where A is selected from, including, but not limited to, methylamine cation, formamidine cation, or Cs⁺, X is selected from F⁻, Cl⁻, Br⁻ or I⁻; the two-dimensional perovskite has a chemical formula of A₃B₂X9, where A is selected from, including, but not limited to, ammonium cation, methylamine cation, formamidine cation, Cs⁺, or Rb⁺, B is selected from Sb³⁺ or Bi³⁺, and X is selected from Br⁻ or I⁻; the zero-dimensional perovskite has a chemical formula of Cs₃Bi₂I₉, Cs₂TeI₆ or Cs₂TeBr₆; and the double perovskite has a chemical formula of Cs₂AgBiBr₆.

3. The solid Frisch grid device based on a perovskite material according to claim 1, wherein a material of the grid electrode metal sheet is selected from, including, but not limited to, gold, copper, tungsten or stainless steel.

4. The solid Frisch grid device based on a perovskite material according to claim 1, wherein a shape of the grid mesh is selected from, including, but not limited to, a wire shape, a strip shape, a mesh shape, a hole shape and a honeycomb shape.

5. The solid Frisch grid device based on a perovskite material according to claim 1, wherein the grid mesh has a thickness of 1 nm-50 mm.

6. The solid Frisch grid device based on a perovskite material according to claim 1, wherein the insulating layer has a thickness of 0 -500 μm.

7. The solid Frisch grid device based on a perovskite material according to claim 1, wherein a material of the insulating layer is selected from an inorganic insulating material or an organic insulating material, wherein the inorganic insulating material is selected from, including, but not limited to, AlN, Al₂O₃ or SiO₂, and the organic insulating material is selected from, including, but not limited to, perylene type C, perylene type N, polytetrafluoroethylene, paraffin or acrylic resin.

8. The solid Frisch grid device based on a perovskite material according to claim 1, wherein a material of the anode or the cathode is selected from, including, but not limited to, platinum, gold, silver, gallium, indium, lead or bismuth.

9. A method for preparing the solid Frisch grid device based on a perovskite material according to claim 1, wherein the preparation method is selected from, including, but not limited to, one or more of direct crystal growth from a solution, mechanical processing and crystal bonding, wherein the direct crystal growth from a solution comprises steps of:
S11: placing a grid mesh on a top of a crystal, and growing the crystal in a precursor solution; and
S12: preparing an anode and a cathode respectively at a top and bottom of the crystal grown in Step S11, to obtain the solid Frisch grid device based on a perovskite material;
the mechanical processing comprises steps of:
S21: cutting a crystal to form a cutting groove and embedding a grid mesh into the cutting groove;
S22: placing the crystal embedded with the grid mesh obtained in Step S21 in a precursor solution for growth; and
S23: preparing an anode and a cathode respectively at a top and bottom of the crystal grown in Step S22, to obtain the solid Frisch grid device based on a perovskite material; and
the crystal bonding comprises steps of:
S31: coating a precursor solution on a surface of a crystal A and covering with a grid mesh;
S32: covering a top of the crystal A covered with the grid mesh obtained in Step S31 with a crystal B;
S33: growing a crystal C in a gap between the crystal A and the crystal B obtained in Step S32 in the presence of the precursor solution, to obtain a crystal embedded with the grid mesh, where the composition of the crystal C and the crystal B is the same as that of the crystal A, and
S34: preparing an anode and a cathode respectively at a top and bottom of the crystal embedded with the grid mesh, to obtain the solid Frisch grid device based on a perovskite material.

10. The preparation method according to claim 9, wherein the precursor solution comprises an organic solvent, and several metal salts as a solute, wherein cations and anions in the metal salts are selected from chemical elements of the crystal.
